(19) United States
(12) Patent Application Publication
(10) Pub. No.: US 2007/0293012 A1
(43) Pub. Date: Dec. 20, 2007

(54) REDUCTION OF SLIP AND PLASTIC DEFORMATIONS DURING ANNEALING BY THE USE OF ULTRA-FAST THERMAL SPIKES

(76) Inventor: Amitabh Jain, Allen, TX (US)

Correspondence Address: TEXAS INSTRUMENTS INCORPORATED, P O BOX 655474, M/S 3999, DALLAS, TX, 75265, US

(21) Appl. No.: 11/762,905

(22) Filed: Jun. 14, 2007

Related U.S. Application Data
(60) Provisional application No. 60/804,744, filed on Jun. 14, 2006.

(51) Int. Cl. H01L 21/336

(52) U.S. Cl. 438/308; 438/795; 438/798

(57) ABSTRACT

Exemplary embodiments provide methods for reducing and/or removing slip and plastic deformations in semiconductor materials by use of one or more ultra-fast thermal spike anneals. The ultra-fast thermal spike anneal can be an ultra-high temperature (UHT) anneal having an ultra-short annealing time. During the ultra-fast thermal spike anneal, an increased annealing power density can be used to achieve a desired annealing temperature required by manufacturing processes. In an exemplary embodiment, the annealing temperature can be in the range of about 1150° C. to about 1390° C. and the annealing dwell time can be on the order of less than about 0.8 milliseconds. In various embodiments, the disclosed spike-annealing processes can be used to fabrication structures and regions of MOS transistor devices, for example, drain and source extension regions and/or drain and source regions.

### RELATED APPLICATIONS

This application claims priority from U.S. Provisional Patent Application Ser. No. 60/804,744, filed Jun. 14, 2006, which is hereby incorporated by reference in its entirety.

### DESCRIPTION OF THE INVENTION

1. Field of the Invention

This invention generally relates to semiconductor fabrication, and, more particularly, to annealing processes during semiconductor fabrication.

2. Background of the Invention

Ultra-high temperature (UHT) annealing is being applied to the next generation of semiconductor devices with a view to maximizing electrical activation while minimizing dopant diffusion. During the UHT annealing, the thermal expansion of the localized heated region relative to the surrounding cooler material can cause slip and plastic deformations in the treated semiconductor material, e.g., a wafer. These deformations can include fracture planes that offset the crystalline structure of the wafer, which can affect the electrical performance of the components subsequently produced. In addition, slip and plastic deformations can weaken the semiconductor material and can lead to rupture of the structure during subsequent heat treatment(s) that are used to produce the components.

The annealing time scale in a conventional UHT annealing process is from about 0.8 milliseconds to about 1 millisecond, or higher. In practice, such annealing time scale limits the maximum anneal temperature to about 1270° C., or else deformations can be incurred.

Thus, there is a need to overcome these and other problems of the prior art and to provide methods for reducing/removing slip and plastic deformations during annealing processes of semiconductor materials.

### SUMMARY OF THE INVENTION

According to various embodiments, the present teachings include a method for annealing a semiconductor material. In this method, a semiconductor material can be spike-annealed at an ultra-high temperature ranging from about 1150° C. to about 1390° C. for less than about 0.8 milliseconds to reduce slip and plastic deformations in the annealed semiconductor material.

According to various embodiments, the present teachings also include a method for annealing a semiconductor material. In this method, an ion-implanted semiconductor material can be provided for annealing. During the annealing process, an annealing power density can be controlled to achieve an increased annealing temperature of about 1280° C. or higher. The ion-implanted semiconductor material can then be annealed for about 0.4 milliseconds or shorter to increase electrical activation and to remove slip and plastic deformations of the annealed ion-implanted semiconductor material.

According to various embodiments, the present teachings further include a method for forming a MOS transistor. During the formation of the MOS transistor, a gate electrode can be formed on a gate dielectric that is formed on a semiconductor substrate. Dopant species can then be implanted into the semiconductor substrate adjacent to the gate electrode. Following the ion-implantation, the semiconductor substrate can be spike-annealed at an ultra-high temperature of about 1150° C. to about 1390° C. for less than about 0.8 milliseconds to reduce slip and plastic deformations in the annealed semiconductor substrate.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate several embodiments of the invention and together with the description, serve to explain the principles of the invention.

FIG. 1 depicts an exemplary method for spike-annealing a semiconductor material with reduced and/or removed slip and plastic deformations in accordance with the present teachings.

FIG. 2 depicts a relationship between the annealing temperature and the dwell time for exemplary spike anneals in accordance with the present teachings.

FIG. 3 depicts a relationship between the power density and the dwell time for exemplary spike anneals in accordance with the present teachings.

FIG. 4 depicts exemplary registration data for processed wafers by various dwell times in accordance with the present teachings.

FIG. 5 depicts exemplary results showing the effect of the dwell time on the sheet resistance dependence upon the annealing temperature of the processed wafers in accordance with the present teachings.

FIG. 6 depicts an exemplary MOS transistor device using ultra-fast spike anneals formed in accordance with the present teachings.

FIG. 7 depicts an exemplary implanted boron profiles under various spike-anneal conditions in accordance with the present teachings.

### DESCRIPTION OF THE EMBODIMENTS

Reference will now be made in detail to the present embodiments (exemplary embodiments) of the invention, examples of which are illustrated in the accompanying drawings. Wherever possible, the same reference numbers will be used throughout the drawings to refer to the same or like parts. In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, merely exemplary.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.” The term “at least one of” is used to mean one or more of the listed items can be selected.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

Exemplary embodiments provide methods for reducing and/or removing slip and plastic deformations in semiconductor materials by use of one or more ultra-fast thermal spike anneals. The ultra-fast thermal spike anneal can be an ultra-high temperature (UHT) anneal having an ultra-short annealing time (also referred to herein as “dwell time” or “annealing dwell time”). During the ultra-fast thermal spike anneal, an increased annealing power density can be used in order to achieve a desired annealing temperature required by manufacturing processes for specific devices and applications. In an exemplary embodiment, the annealing temperature can be in a range of about 1150° C. to about 1390° C. and the dwell time scale can be on the order of less than about 0.8 milliseconds to reduce and/or remove slip and plastic deformations in the annealed semiconductor material. In an additional exemplary embodiment, the annealing temperature can be higher, for example, in a range from about 1280° C. or higher and the dwell time scale can be on the order of about 0.4 milliseconds or shorter. In various embodiments, the disclosed spike-annealing processes can be used to fabrication structures and regions of MOS transistor devices, for example, drain and source extension regions and/or drain and source regions.

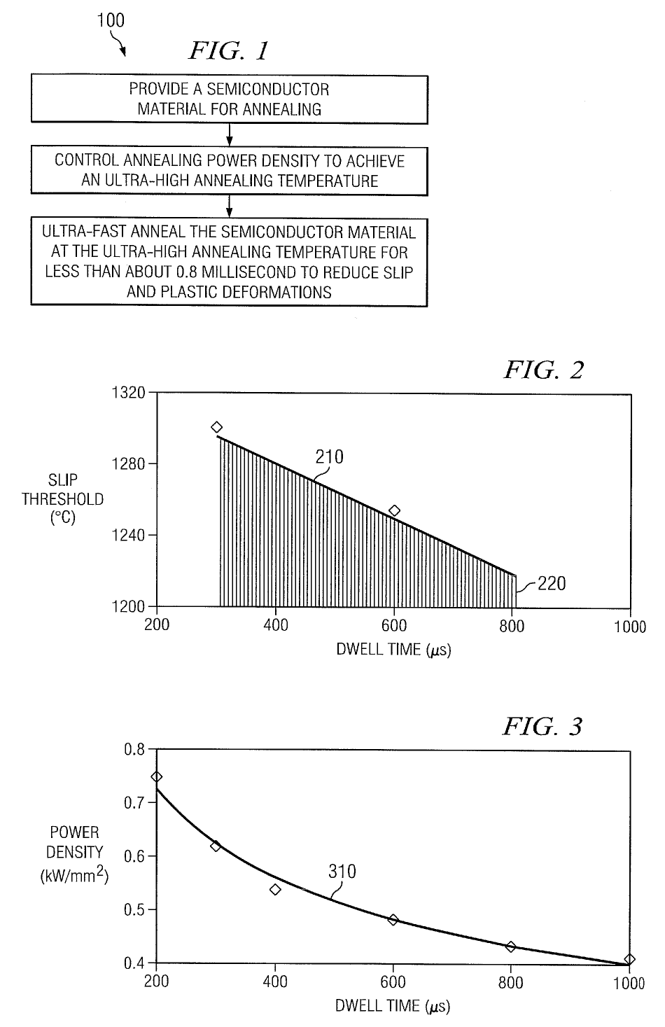

FIG. 1 depicts an exemplary method 100 for annealing a semiconductor material with reduced and/or removed slip and plastic deformations in accordance with the present teachings. At 110, a semiconductor material, for example, an ion-implanted semiconductor layer in MOS transistor devices, can be provided for annealing to increase/maximize electrical activation while to decrease/minimize dopant diffusion. The semiconductor material can include, for example, Si, Ge, Si—Ge or GaAs. During MOS transistor manufacturing processes, as known to one of ordinary skill in the art, semiconductor regions, for example, deep well regions, drain and source regions, drain and source extension regions, etc., can often be implanted with various dopant species. For example, various n-type and/or p-type dopants can be implanted into the desired semiconductor regions. Exemplary n-type dopants can include, but are not limited to, arsenic, phosphorous, and/or antimony and exemplary p-type dopants can include, but are not limited to, boron, gallium and/or indium. After the implantation process of the semiconductor material, an ultra-high temperature annealing (UHT) process can be performed.

At 120, a desired annealing temperature can be achieved by controlling the annealing power density. For example, by increasing the annealing power density, the annealing temperature can be increased having an exemplary temperature of about 1300° C. or higher. The annealing temperatures can be required by the manufacturing processes on the semiconductor materials depending on the device fabrication stages and applications. In various embodiments, the power density can be controlled through a power source including a laser, flash lamp or arc lamp. In various embodiments, the power density can be controlled to be about 0.4 kW/mm² to about 1.0 kW/mm².

At 130, ultra-fast thermal spike anneals, for example, as fast as less than about 0.8 milliseconds, can then be performed to anneal the exemplary ion-implanted semiconductor material at a controlled annealing temperature of about 1150° C. to about 1390° C., in order to reduce and/or remove the generation of slip and plastic deformations in the annealed semiconductor material.

In general, the deformations of a material, e.g., slip lines and plastic deformations in a semiconductor material, depend on the strain rate generated in the material. During the UHT (ultra-high temperature) annealing processes, only the region of the wafer coupled to the heat source, e.g., an implanted region by design, can experience a large temperature rise (e.g., on the order of several hundred degrees Celsius). In this case, the rest of the wafer can serve as a heat sink during subsequent cool-down. However, the localized heated region can be under high strain, since thermal expansion is prevented by the surrounding regions. Under conditions of high strain-rates, semiconductor materials, for example, silicon, can have plasto-elastic behavior. The plasto-elastic behavior can be analogous to visco-elastic behavior by a known model, for example, the Maxwell model that includes a spring and dashpot in series. This model represents a liquid that is able to have irreversible (viscous) deformations with some additional reversible (elastic) deformations.

In the case where the dwell time is long, for example, on the order of about 0.8 milliseconds or longer as used in the art, the semiconductor material can show a plastic (viscous) property, because the long dwell time scale can generate low strain rates (e.g., with strain cycles over several milliseconds or more) to provide enough time for dislocations to respond (i.e., to move) and slip and plastic deformations can then be occurred.

In the case where the dwell time is ultra-fast, for example, on the order of shorter than about 0.8 milliseconds, the semiconductor material can show an elastic property and there can be an activation energy associated with dislocation motion and provide a barrier to generate slip and plastic deformations. In this case, the semiconductor material can correspond to the “spring” of the Maxwell model having an “elastic component” occur instantaneously, and relax immediately upon release of the strain without developing slip lines and plastic deformations. That is, the ultra-fast time scale can enable the semiconductor material (e.g., silicon), to plasto-elastically support the high strain-rates that may arise during the UHT (ultra-high temperature) annealing process. Therefore, by limiting the process time in the sub-milliseconds range (e.g., shorter than about 0.8 milliseconds), generation of slip and plastic deformations can be controlled, i.e., reduced and/or removed.

In this manner, as shown in the method 100 of FIG. 1, semiconductor materials, e.g., ion-implanted semiconductor layers/regions, can be annealed ultra-fast at desired annealing temperatures to reduce and/or remove deformations. FIG. 2 depicts a relationship between the annealing temperature and the annealing dwell time for various exemplary spike anneals in accordance with the present teachings. Specifically, FIG. 2 includes a curve 210 and a region 220, which covers an area formed under the curve 210. The curve 210 depicts a slip threshold temperature (i.e., temperature at which slip appears) as a function of the dwell time for an exemplary process, in which semiconductor material Si—Ge epitaxy can be used for channel strain engineering and a laser can be used as the heat source. As shown, as the annealing dwell time reduces from about 0.8 milliseconds to about 0.3 milliseconds, the annealed materials, i.e., the ion-implanted Si—Ge semiconductor materials, can be annealed at a high temperature of about 1300° C. (when the dwell time is 0.3 milliseconds) without incurring slip and plastic deformations. The region 220 under the plot 210 can thus be a slip-free region with various annealing times corresponding to various annealing temperatures. For example, if a semiconductor production requires an annealing treatment at about 1280° C. or higher, the annealing time can be about 0.4 milliseconds or shorter in the region 220 for a slip-free process.

FIG. 3 depicts a relationship between the power density and the annealing dwell time for various exemplary ultra-fast thermal spike anneals in accordance with the present teachings. The power density can be a laser power density on the wafer that is required to reach a necessary/desired annealing temperature. In an exemplary embodiment, the power density can be required to reach the melting point of the exemplary silicon. As shown by the plot 310 in FIG. 3, when the annealing time is shortened, the required power density needs to be increased in order to provide a suitable high temperature. However, as indicated, when the dwell time is shortened by a factor of five, the power required can only be increased by a factor of two. This is because the volume of silicon heated at shorter time can be decreased and thus making it easier to achieve a desired surface temperature.

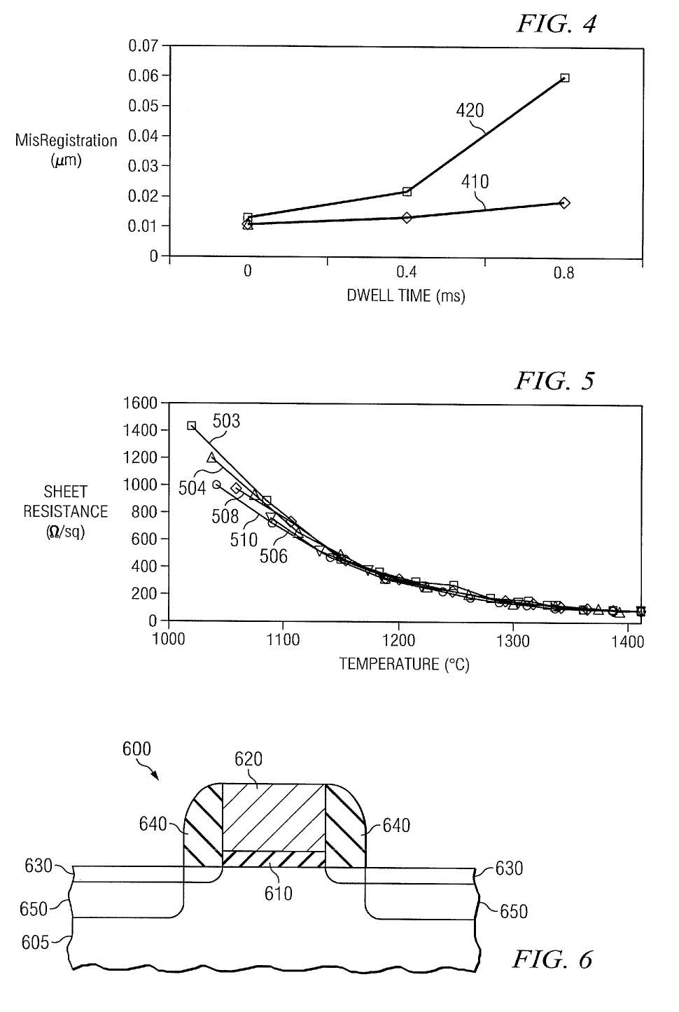

FIG. 4 depicts exemplary registration data for processed wafers using various dwell times in accordance with the present teachings. Specifically, FIG. 4 depicts mis-registration data in an x-direction (see plot 410) and a y-direction (see plot 420) of the processed wafers before and after the ultra-high temperature (UHT) annealing at various annealing dwell times. As shown, when the dwell time decreases from about 0.8 milliseconds through about 0.4 milliseconds to about 0 milliseconds (i.e., no anneal), the mis-registration of the processed wafers in either x-direction (see plot 410) or y-direction (see plot 420) can be decreased and the manufacturing quality can be increased. On the other hand, as can be indicated from FIG. 4, when the dwell time is longer, e.g., more than 0.8 milliseconds, the mis-registration can be increased for the processed wafers before and after the UHT annealing processes.

FIG. 5 depicts exemplary results showing the effect of the dwell time on the sheet resistance dependence upon the annealing temperature of the processed wafers in accordance with the present teachings. In this example, the processed wafers can be a boron implanted semiconductor layer of a MOS transistor device and the boron implanted semiconductor layer can be annealed at various dwell times, for example, about 0.3, 0.4, 0.6, 0.8, and 1.0 milliseconds, as shown by curves 503, 504, 506, 508 and 510, respectively. In all of these cases as indicated, the sheet resistance of the processed wafers can be decreased as the annealing temperature is increased. Therefore, a high annealing temperature can be necessary for a low sheet resistance of manufacturing processes. In addition, when the annealing time is reduced shorter than 0.8 milliseconds (see curves 503, 504, and 506), e.g., in order to avoid the generation of slip and plastic deformations, high annealing temperature can still be reached for a low sheet resistance. It has therefore been discovered that there is a distinct advantage in being able to go the higher temperature even if the annealing dwell time is ultra-short in accordance with the present teachings.

In various embodiments, the disclosed ultra-fast thermal spike anneals can be used in forming MOS transistor devices. FIG. 6 depicts an exemplary MOS transistor device 600 using ultra-fast thermal spike anneals during its formation in accordance with the present teachings. It should be readily apparent to one of ordinary skill in the art that the transistor device 600 depicted in FIG. 6 represents a generalized schematic illustration and that other regions/layers/species can be added or existing regions/layers/species can be removed or modified.

In FIG. 6, the device 600 includes a semiconductor substrate 605, a gate dielectric layer 610, a gate electrode 620, drain and source extension regions 630, sidewall structures 640 and drain and source regions 650. The gate electrode 620 can be stacked on the gate dielectric layer 610, which can be formed on the semiconductor substrate 605. The sidewall structures 640 can be formed along the sidewalls of the stacked gate electrode 620 and the gate dielectric layer 610 and on the semiconductor substrate 605. The drain and source extension regions 630 can be formed adjacent to the gate electrode 620 in the semiconductor substrate 605. The drain and source regions 650 can be formed adjacent to the sidewall structure 630 and in the semiconductor substrate 605.

The semiconductor substrate 605 can be a doped region formed inside a semiconductor material, for example, inside an epitaxial layer or inside a semiconductor substrate. Depending on the types of MOS transistor devices, the doped region can be N-type or N-type doped by respective dopant species known to one of ordinary skill in the art.

The gate dielectric layer 610 can be formed on the semiconductor substrate 605. The gate dielectric layer 610 can include, for example, silicon oxide, silicon oxynitride, or any suitable dielectric layer material. The MOS transistor gate electrode 620 can be formed on the gate dielectric layer 610 and can include, for example, doped polycrystalline silicon, a metal, or any suitable conductor material.

The drain and source extension regions 630 can be formed following the formation of the gate electrode 620. In various embodiments, the drain and source extension regions 630 can be formed by first implanting desired n-type or p-type dopants into the semiconductor substrate 605 and adjacent to the gate electrode 620, followed by one or more ultra-fast thermal spike anneals to reduce and/or remove slip and plastic deformations in these regions (i.e., 630), and thus to increase the electrical activation and to decrease dopant diffusion of the regions (i.e., 630). For example, the n-type dopants can include arsenic, phosphorous, and/or antimony, and the p-type dopants can include boron, gallium, and/or indium. In various embodiments, the implanted drain and source extension regions 630 can be annealed at a temperature of about 1150° C. to about 1390° C. controlled by an increased power density having a dwell time of, for example, shorter than about 0.8 milliseconds.

Sidewall structures 640 can be formed using standard semiconductor manufacturing methods following the formation of the drain and source extension regions 630, which can include ion implantation processes and ultra-fast spike anneals. In various embodiments, the sidewall structure 640 can be formed following the ion implantation processes of the drain and source extension regions 630 but prior to the ultra-fast spike anneals of the drain and source extension regions 630. That is, the ultra-fast spike anneals of the drain and source extension regions 630 can be performed after the formation of the sidewall structure 640.

The MOS transistor drain and source regions 650 can then be formed by implanting n-type or p-type dopants into the semiconductor substrate 605. In various embodiments, the drain and source regions 650 can be formed by first implanting desired n-type or p-type dopants into the semiconductor substrate 605 and adjacent to the sidewall structure 640, followed by one or more ultra-fast thermal annealing spikes to reduce and/or remove slip and plastic deformations in these regions (i.e., 640). Exemplary n-type dopants can include arsenic, phosphorous, and/or antimony, and exemplary p-type dopants can include boron, gallium, and/or indium. In various embodiments, the implanted drain and source regions 650 can be annealed at a temperature of about 1150° C. to about 1390° C. controlled by an increased power density having a dwell time of, for example, shorter than about 0.8 milliseconds. In various embodiments, the drain and source regions 650 can be formed prior to the formation of the drain and source extension regions 630. In these embodiments, disposable sidewall structures (not shown) can be used.

In various embodiments, one or more the ultra-fast spike anneals following the ion implantation of the drain and source extension regions 630 can be omitted, while the drain and source extension regions 630 and the drain and source regions 650 can be annealed simultaneously using common ultra-fast spike anneal(s). The common spike anneals can include annealing the regions 630, and 650 at a temperature from about 1150° C. to about 1390° C. for less than about 0.8 milliseconds.

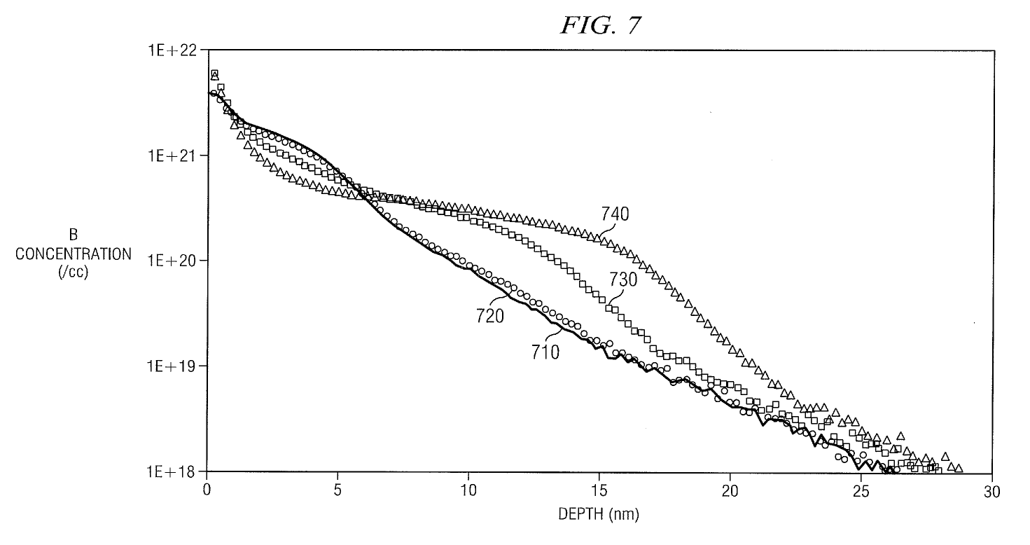

In this manner, the disclosed ultra-fast thermal spike anneal(s) can be used to form the regions 630 and 650 to reduce slip and plastic deformations and to provide desired low sheet resistance (i.e., high electrical conductance). Generally, the junction depth and the implanted ion concentration profile can be critical for these regions (i.e., 630 and 650) in obtaining a low sheet resistance. FIG. 7 shows an evolution of an implanted boron profile under various spike anneal conditions in accordance with the present teachings. As shown, FIG. 7 includes implanted boron concentration profile curves 710, 722, 724 and 726 after a spike anneal at annealing temperatures of about 950° C., 1250° C., 1300° C. and 1350° C., respectively. The continuous curve 710, obtained after a spike anneal at 950° C., can represent the boron concentration profile after a spacer loop (i.e., the formation of the sidewall structure 640) in an exemplary device flow. As indicated from the curves 722, 724 and 726, the exemplary boron concentration profile can evolve rapidly in the ultra-high temperature ranges due to concentration-enhanced diffusion. It is therefore necessary to anneal at higher temperatures, for example, over 1300° C. (see curves 724 and 726) during the ultra-fast thermal spike anneals, in order to have good electrical conductance (i.e., high ion concentration) for the resulting semiconductor regions. In various embodiments, the ion-implanted semiconductor materials, e.g., the regions 630 and 650 can be annealed at a temperature of about 1280° C. or higher for about 0.4 milliseconds or shorter in order to increase electrical activation and to reduce/remove slip and plastic deformations of the annealed semiconductor materials or regions. In this case, a power density of about 0.6 kW/mm² to about 1 kW/mm² can be used to obtain such high temperature.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method for annealing a semiconductor material comprising:
providing a semiconductor material for annealing; and
spike-annealing the semiconductor material at an ultra-high temperature of about 1150° C. to about 1390° C. for less than about 0.8 milliseconds to reduce slip and plastic deformations in the annealed semiconductor material.

2. The method of claim 1, wherein the ultra-high temperature can be obtained by increasing power density of a power source, wherein the power source comprises a laser, flash lamp or arc lamp.

3. The method of claim 2, wherein the power density of the spike anneal is about 0.4 kW/mm² to about 1.0 kW/mm².

4. The method of claim 1, further comprising spike-annealing the semiconductor material at an ultra-high temperature of about 1280° C. or higher for about 0.4 milliseconds or shorter to remove slip and plastic deformations of the semiconductor material.

5. The method of claim 1, the semiconductor material is an ion-implanted semiconductor material.

6. The method of claim 1, wherein the semiconductor material is implanted with a dopant species selected from the group consisting of boron, gallium and indium.

7. The method of claim 1, wherein the semiconductor material is implanted with a dopant species selected from the group consisting of arsenic, phosphorous, and antimony.

8. The method of claim 1, wherein the semiconductor material is selected from the group consisting of Si, Ge, Si—Ge, and GaAs.

9. The method of claim 1, wherein the semiconductor material is used as one or more of drain and source regions and drain and source extension regions of a MOS transistor device.

10. A method for annealing a semiconductor material comprising:
providing an ion-implanted semiconductor material for annealing;
increasing an annealing power density in an amount to achieve an increased annealing temperature of about 1280° C. or higher; and
annealing the ion-implanted semiconductor material for about 0.4 milliseconds or shorter to increase electrical activation and to remove slip and plastic deformations of the annealed ion-implanted semiconductor material.

11. The method of claim 10, further comprising a power source to increase the annealing power density, wherein the power source comprises a laser, flash lamp or arc lamp.

12. The method of claim 10, wherein the increased power density is about 0.6 kWw/mm² to about 1.0 kW/mm².

13. The method of claim 10, wherein the ion-implanted semiconductor material comprises a material selected from the group consisting of Si, Ge, Si—Ge, and GaAs.

14. The method of claim 10, wherein the ion-implanted semiconductor material is used as one of drain and source regions and drain and source extension regions of a MOS transistor device.

15. A method for forming a MOS transistor comprising:
forming a gate electrode on a gate dielectric on a semiconductor substrate, implanting dopant species into the semiconductor substrate adjacent to the gate electrode; and
spike-annealing the semiconductor substrate at an ultra-high temperature of about 1150° C. to about 1390° C. for less than about 0.8 milliseconds to reduce slip and plastic deformations in the annealed semiconductor substrate.

16. The method of claim 15, wherein the ultra-high temperature can be obtained by increasing a power density of a power source, wherein the power source comprises a laser, flash lamp or arc lamp.

17. The method of claim 16, wherein the power density is about 0.4 kW/mm² to about 0.8 kW/mm².

18. The method of claim 15, further comprising spike-annealing the semiconductor substrate at an ultra-high temperature of about 1280° C. or higher for about 0.4 milliseconds or shorter to increase electrical activation and to remove slip and plastic deformations of the annealed semiconductor substrate.

19. The method of claim 15, further comprising forming a sidewall structure along each sidewall of the gate electrode and the gate dielectric following the dopant species implantation and prior to the spike-anneal.

20. The method of claim 15, further comprising forming a sidewall structure along each sidewall of the gate electrode and the gate dielectric after the spike-anneal.

21. The method of claim 15, further comprising:
implanting dopant species into the semiconductor substrate adjacent to the gate electrode,
forming a sidewall structure along each sidewall of the gate electrode and the gate dielectric,
implanting a second dopant species into the semiconductor substrate adjacent to the sidewall structure, and
spike-annealing the semiconductor substrate at an ultra-high temperature of about 1150° C. to about 1390° C. for less than about 0.8 milliseconds.
